(19) United States
(12) Patent Application Publication
(10) Pub. No.: US 2014/0354447 A1
(43) Pub. Date: Dec. 4, 2014

(54) ANALYZING SYSTEM AND METHOD FOR POWER DATA

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: YONG-CHANG FAN, Wuhan (CN); LI-FU XU, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/154,567

(22) Filed: Jan. 14, 2014

(30) Foreign Application Priority Data
Jun. 3, 2013 (CN) 201310215947X

(51) Int. Cl. G01D 4/00

(52) U.S. Cl. CPC G01D 4/002
USPC 340/870.02

(57) ABSTRACT

An analyzing system includes a retrieving module, a filtering module, an extracting module, a display module, and a storing module. The retrieving module is used to retrieve a data package. The filtering module is used to filter a power data parameter from the data package. The extracting module is used to extract a power data parameter value from the power data parameter. The display module is used to display the power data parameter value. The storing module is used to store the power data parameter value. The disclosure further offers an analyzing method.

### BACKGROUND

1. Technical Field

The present disclosure relates to analyzing systems and analyzing methods, and particularly to an analyzing system and method for a power data.

2. Description of Related Art

Power analyzers are used to measure various parameters of different devices, such as a motor, an electrical machine, and a voltage transformer. The various parameters comprise a voltage, a current, a frequency. However, it is time-consuming to adjust the power analyzer if it is measuring the parameter. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like-reference numerals designate corresponding parts throughout the several views.

FIG. 1 is a block diagram of an embodiment of an analyzing system.

FIG. 2 is a flowchart of an embodiment of an analyzing method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

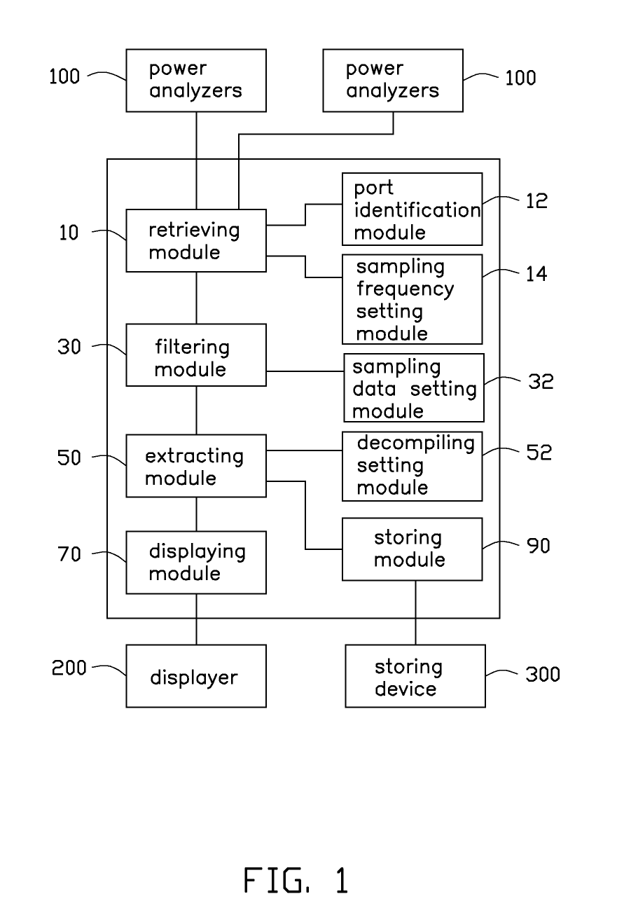

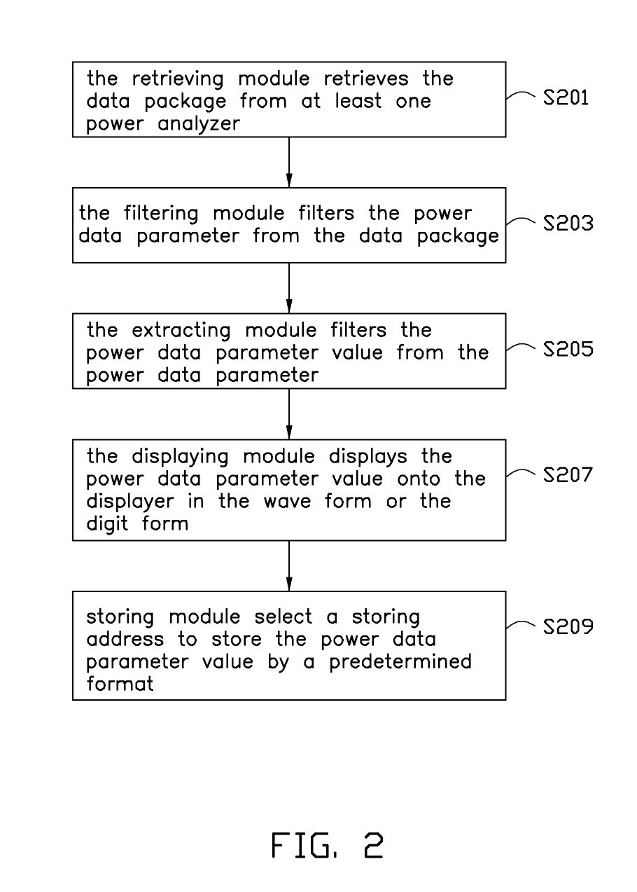

FIGS. 1-2 illustrate an embodiment of an analyzing system. The analyzing system can be connected to one or more power analyzers 100 and be used to analyze data of each power analyzer 100. A display 200 and a storing device 300 are connected to the analyzing system. The display 200 is used to display the data that is analyzed by the one or more power analyzers 100. The storing device 300 is used to store the data that is analyzed by the one or more power analyzers 100.

The analyzing system includes a retrieving module 10, a filtering module 30, an extracting module 50, a display module 70, and a storing module 90.

The retrieving module 10 is connected to a port identification module 12 and a sampling frequency setting module 14. The retrieving module 10 is used to scan and connect a port of each power analyzer 100. In one embodiment, the retrieving module 10 is connected to a power analyzer 100 via a RS-232 serial interface or connected to a number of power analyzers 100 via a RS 485 parallel interface. The port identification module 12 is used to identify different ports to suit different types of power analyzers 100. The sampling frequency setting module 14 is used to set a frequency that is retrieved by the retrieving module 10. The retrieving module 10 is used to a data package from the one or more power analyzers 100. The data package of the one or more power analyzers 100 comprises a plurality of power data parameters, such as a voltage, a current, a power value, and a power factor. The retrieving module 10 can obtain the data package via different transmitting formats, such as ASCII or hexadecimal.

The filtering module 30 is connected to a sampling data setting module 32. The sampling data setting module 32 is used to set a power data parameter, such as the voltage and the current. The filtering module 30 is used to filter the power data parameter from the data package according to the sampling data setting module 32. The filtering module 30 is further used to transmit the power data parameter to the extracting module 50.

The extracting module 50 is connected to a decompiling setting module 52. The power data parameter comprises a transmitting lead message, a power data parameter value, and a data verification value. The decompiling setting module 52 is used to set a decompiling regulation. The extracting module 50 is used to extract the power data parameter value from the power data parameter according to the decompiling setting module 52.

The display module 70 is used to display the power data parameter value onto the display 200 in a wave form or a digit form. In one embodiment, the display module 70 is further used to display the working position of the analyzing system.

The storing module 90 is used to select a storing address to store the power data parameter value by a predetermined format. Thus, the power data parameter value cannot be lost.

FIG. 2 illustrates an embodiment of an analyzing method. The method comprises the following steps:

S201: the retrieving module 10 retrieves the data package from at least one power analyzer 100. The retrieving module 10 scans a suitable port of the at least one power analyzer 100 and retrieves the data package according to a sampling frequency that has been set by the sampling frequency setting module 14.

S203: the filtering module 30 filters the power data parameter from the data package, such as the current and the voltage.

S205: the extracting module 50 filters the power data parameter value from the power data parameter. The power data parameter comprises the transmitting head message, the power data parameter value, and the data verification value. The extracting module 50 filters the power data parameter value according to the predetermined format.

S207: The display module 70 displays the power data parameter value onto the display 200 in the wave form or the digit form.

S209: storing module 90 is used to select a storing address to store the power data parameter value by a predetermined format.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An analyzing system comprising:
a retrieving module configured to retrieve a data package;
a filtering module configured to filter a power data parameter from the data package;
an extracting module configured to extract a power data parameter value from the power data parameter;
a display module configured to display the power data parameter value; and
a storing module configured to store the power data parameter value.

2. The analyzing system of claim 1, wherein the retrieving module is connected to a port identification module, the port identification module is configured to identify different ports to suit the retrieving module with a power analyzers.

3. The analyzing system of claim 2, wherein the retrieving module is further connected to a sampling frequency setting module, the sampling frequency setting module is configured to set a sampling frequency, and the retrieving module is configured to retrieve the data package according to the sampling frequency.

4. The analyzing system of claim 1, wherein the power data parameter comprises the power data parameter value and a data verification value.

5. The analyzing system of claim 1, wherein the filtering module is connected to a sampling data setting module, and the sampling data setting module is configured to set the power data parameter for the filtering module.

6. The analyzing system of claim 1, wherein the extracting module is connected to a decompiling setting module, the decompiling setting module is configured to set a decompiling regulation, and the extracting module is configured to extract the power data parameter value from the power data parameter according to the decompiling regulation.

7. The analyzing system of claim 1, wherein the storing module is configured to select a storing address to store the power data parameter value by a predetermined format.

8. An analyzing method comprising:
retrieving a data package by a retrieving module;
filtering a power data parameter from the data package by a filtering module;
extracting a power data parameter value from the power data parameter by an extracting module;
displaying the power data parameter value by a display module; and
storing the power data parameter value by a storing module.

9. The analyzing method of claim 8, further comprising: identifying different ports to suit the retrieving module with a power analyzer by a port identification module before retrieving the data package by the retrieving module.

10. The analyzing method of claim 8, further comprising: setting a sampling frequency by a sampling frequency setting module before retrieving the data package by the retrieving module.

11. The analyzing method of claim 8, wherein the power data parameter comprises the power data parameter value and a data verification value.

12. The analyzing method of claim 8, further comprising: setting the power data parameter for the filtering module by a sampling data setting module before filtering the power data parameter from the data package by the filtering module.

13. The analyzing method of claim 8, wherein setting a decompiling regulation by a decompiling setting module before extracting the power data parameter value from the power data parameter by the extracting module.

14. The analyzing method of claim 8, wherein selecting a storing address to store the power data parameter value with a predetermined format by the storing module when storing the power data parameter value by the storing module.
